(19) United States
(12) Patent Application Publication
(10) Pub. No.: US 2017/0025447 A1
(43) Pub. Date: Jan. 26, 2017

(54) DISPLAY DEVICE AND MANUFACTURING METHOD THEREOF

(71) Applicant: Samsung Display Co., Ltd., Yongin-si (KR)

(72) Inventors: Jun Hyun PARK, Suwon-si (KR); Sung Hwan KIM, Yongin-si (KR); Se Young SONG, Hwaseong-si (KR); Kyoung Ju SHIN, Hwaseong-si (KR)

(21) Appl. No.: 14/995,675

(22) Filed: Jan. 14, 2016

(30) Foreign Application Priority Data
Jul. 21, 2015 (KR) 10-2015-0102881

(51) Int. Cl. H01L 27/12; H01L 49/02

(52) U.S. Cl. CPC H01L 27/1255; H01L 27/1248; H01L 27/124; H01L 27/1222; H01L 27/1259; H01L 28/60

(57) ABSTRACT

A display device includes a substrate, a thin film transistor, a storage electrode, a pixel electrode, and a common electrode. The thin film transistor is disposed on the substrate and includes a drain electrode and a semiconductor layer. The storage electrode is disposed at a same layer as the semiconductor layer. The pixel electrode is disposed on the substrate and is electrically connected to the drain electrode. The common electrode is disposed on the substrate.

### CROSS-REFERENCE TO RELATED APPLICATION

This application claims priority from and the benefit of Korean Patent Application No. 10-2015-0102881, filed on Jul. 21, 2015, which is hereby incorporated by reference for all purposes as if fully set forth herein.

### BACKGROUND

Field

Exemplary embodiments relate to a display device and a manufacturing method thereof.

Discussion

A display device, such as a liquid crystal display (LCD) or an organic light emitting diode display (OLED), may include a thin film transistor serving as a switching element and a storage capacitor serving as a storage element. The storage capacitor serves to maintain voltage by accumulating charge, and, when utilized in association with a pixel, an applied voltage to the pixel may be maintained even after the thin film transistor is turned off.

For example, the storage capacitor may include a pixel electrode and a storage electrode formed of a gate conductor. An insulating layer may be disposed between the pixel electrode and the storage electrode. Wires for transferring signals, such as gate conductors, typically have small resistance, and, as such, may be made of a metal. It is noted, however, that the metal reflects light instead of transmitting the light. Accordingly, when an area of the storage electrode is increased, an aperture ratio or a transmittance of a pixel may be reduced.

As a resolution of the display device is increased, pitches between adjacent pixels may be reduced, thereby reducing a region in which the storage electrode can be formed. This may result in reduced capacitance of the storage capacitor that may be greater than a reduced parasitic capacitance of the thin film transistor. As a result, a kick-back voltage may be increased, which may degrade image quality. Sufficient capacitance of the storage capacitor is, therefore, utilized to maintain an applied voltage or suppress an increase in the kick-back voltage. This means, however, that there may be a limitation in reducing the area in which a storage electrode may be formed. To this end, it is inevitable to attempt to form the storage electrode using a complex method or to cause a reduction in the aperture ratio.

The above information disclosed in this Background section is only for enhancement of understanding of the background of the inventive concept, and, therefore, it may contain information that does not form the prior art that is already known in this country to a person of ordinary skill in the art.

### SUMMARY

One or more exemplary embodiments provide an increased storage capacitance without reduction in the aperture ratio of a display device.

One or more exemplary embodiments provide a transparent storage electrode in an opening of a pixel that may be formed without using an additional mask.

Additional aspects will be set forth in the detailed description which follows, and, in part, will be apparent from the disclosure, or may be learned by practice of the inventive concept.

According to one or more exemplary embodiments, a display device includes a substrate, a thin film transistor, a storage electrode, a pixel electrode, and a common electrode. The thin film transistor is disposed on the substrate and includes a drain electrode and a semiconductor layer. The storage electrode is disposed at a same layer as the semiconductor layer. The pixel electrode is disposed on the substrate and is electrically connected to the drain electrode. The common electrode is disposed on the substrate.

According to one or more exemplary embodiments, a method of manufacturing a display device includes: forming a gate electrode on a substrate; forming a gate insulating layer on the substrate; forming a semiconductor layer on the gate insulating layer; forming a photosensitive film pattern covering a first region of the semiconductor layer corresponding to a thin film transistor and exposing a second region of the semiconductor layer corresponding to a storage electrode; forming the storage electrode by diffusing hydrogen or fluorine in the second region, the storage electrode being conductive; removing the photosensitive film pattern; forming, on the substrate, a source electrode and a drain electrode; and forming, on the substrate, a common electrode.

According to one or more exemplary embodiments, storage capacitance can be increased by increasing an area of the storage electrode. Since the storage electrode can be formed using a mask used for direct connection between the gate conductor and the data conductor, an additional mask is not required to form the storage electrode, however, may be utilized if desired. Further, the storage electrode being formed of a transparent conductor enables formation of the storage electrode in an opening of a pixel, and, as such, an aperture ratio is not reduced due to the presence of the storage electrode in the opening.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 schematically illustrates a configuration of a display device, according to one or more exemplary embodiments.

FIG. 2 is a layout view illustrating a pixel area of a display device, according to one or more exemplary embodiments.

FIG. 3 is a layout view of a thin film transistor included in a gate driver of a display device, according to one or more exemplary embodiments.

FIG. 4 is a cross-sectional view of the thin film transistor taken along sectional line B-B of FIG. 2 and sectional line C-C of FIG. 3, according to one or more exemplary embodiments.

FIGS. 5 to 11 are respective cross-sectional views of a display device at various stages of manufacture, according to one or more exemplary embodiments.

FIG. 12 is a layout view illustrating a pixel area of a display device, according to one or more exemplary embodiments.

FIG. 13 is a cross-sectional view of a pixel taken along sectional line D-D of FIG. 12, according to one or more exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

Unless otherwise specified, the illustrated exemplary embodiments are to be understood as providing exemplary features of varying detail of various exemplary embodiments. Therefore, unless otherwise specified, the features, components, modules, layers, films, panels, regions, and/or aspects of the various illustrations may be otherwise combined, separated, interchanged, and/or rearranged without departing from the disclosed exemplary embodiments. Further, in the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms “first,” “second,” etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

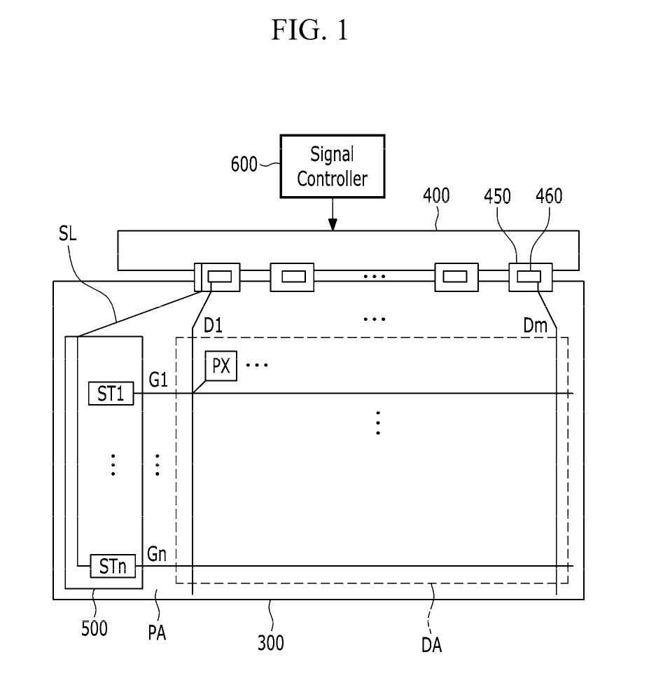

FIG. 1 schematically illustrates a configuration of a display device, according to one or more exemplary embodiments.

Referring to FIG. 1, the display device includes a display panel 300, a data driver 460, a gate driver 500, and a signal controller 600. The display panel 300 includes a display area DA for displaying an image, and a peripheral area PA disposed outside the display area DA, e.g., disposed around the display area DA. The gate driver 500 and the data driver 460 may be disposed in the peripheral area PA. The gate driver 500 may be configured to apply a gate voltage to gate lines G1 to Gn (n being a natural number), whereas the data driver 460 may be configured to apply a data voltage to data lines D1 to Dm (m being a natural number).

The data driver 460 may be an integrated circuit (IC) formed on a flexible printed circuit board (FPCB) 450 attached to (or otherwise mounted on) the display panel 300. The data lines D1 to Dm may extend from the display area DA to the peripheral area PA to form at least a part of a fan-out portion (not illustrated) in the peripheral area PA. The gate driver 500 and the data driver 460 may be controlled by the signal controller 600. A printed circuit board (PCB) 400 may be disposed outside of the FPCB 450 to transfer a signal from the signal controller 600 to the data driver 460 and the gate driver 500. The signal supplied from the signal controller 600 to the gate driver 500 may include first signals, such as vertical start signals STV and clock signals CKV and CKVB, and a second signal, such as a low voltage VSS of a specific level. It is contemplated, however, that the signal may include various types of vertical start signals and/or clock signals, as well as two kinds of low voltages.

Although not illustrated, the display area DA may include a thin film transistor, a storage capacitor, and the like. According to one or more exemplary embodiments, the display device may be a liquid crystal display. As such, the display area DA may include a liquid crystal capacitor, and the liquid crystal capacitor may include a liquid crystal layer. The liquid crystal layer may be filled via a corresponding microcavity (not illustrated) for every one or a plurality of pixel areas. According to one or exemplary embodiments, the display device may be an organic light emitting diode display. To this end, the display area DA may include a light-emitting device. A plurality of gate lines G1 to Gn and a plurality of data lines D1 to Dm are disposed in the display area DA. The gate lines G1 to Gn and the data lines D1 to Dm may cross each other while being insulated from each other.

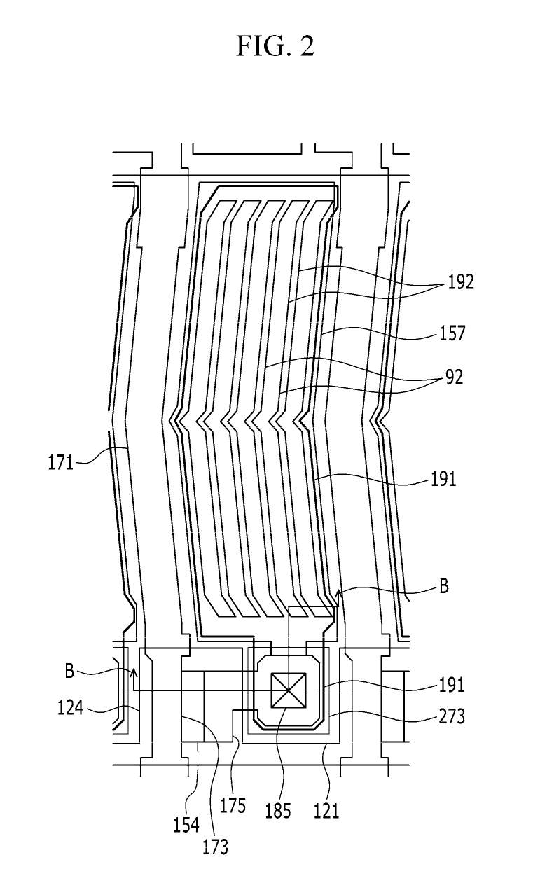

In association with liquid crystal display embodiments, a pixel PX may include a thin film transistor, a liquid crystal capacitor, and at least one storage capacitor. A control terminal of the thin film transistor may be connected to a corresponding gate line, an input terminal of the thin film transistor may be connected to a corresponding data line, and an output terminal of the thin film transistor may be connected to first terminals of the liquid crystal capacitor and the storage capacitor. A second terminal of the liquid crystal capacitor may be connected to a common electrode configured to receive a common voltage, and a second terminal of the storage capacitor may be configured to receive a storage voltage. The storage voltage may be the same as the common voltage. A liquid crystal display embodiment will be described in more detail in association with FIGS. 2-4.

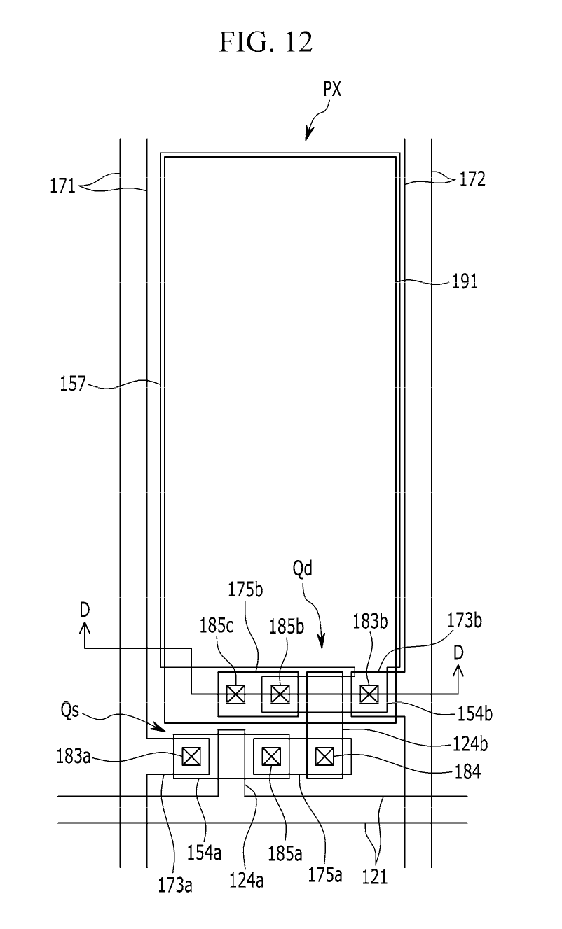

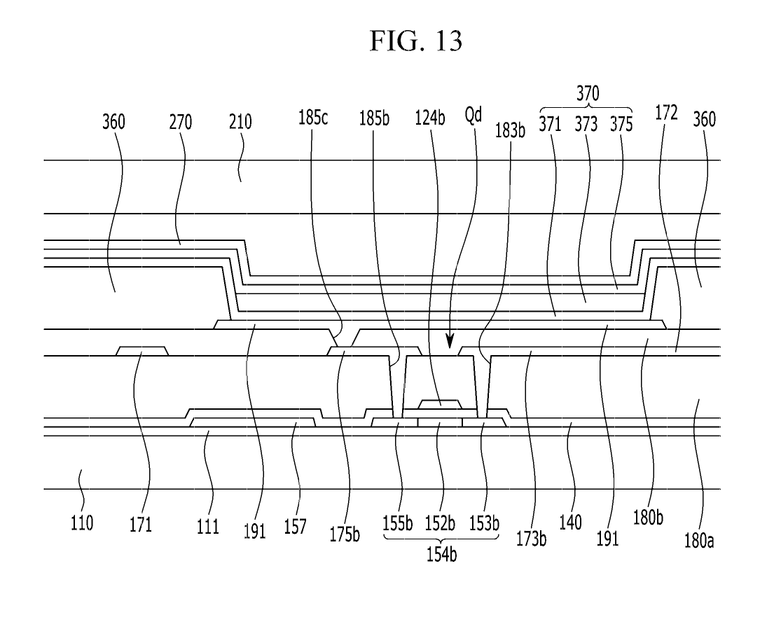

In association with organic light emitting diode display embodiments, a pixel PX may include at least two thin film transistors including a switching thin film transistor and a driving thin film transistor, at least one storage capacitor, and a light-emitting device. An organic light emitting diode display embodiment will be described in more detail in association with FIGS. 12 and 13.

The data lines D1 to Dm may receive data voltages from the data driver 460, and the gate lines G1 to Gn may receive gate voltages from the gate driver 500. The data driver 460 may be disposed at an upper or lower side of the display panel 300 and connected to the data lines D1 to Dm.

The gate driver 500 may generate gate voltages (e.g., a gate-on voltage and a gate-off voltage) by receiving low voltages corresponding to a vertical start signal, a clock signal, and a gate-off voltage to apply them to the gate lines G1 to Gn. The gate driver 500 may include a plurality of stages ST1-STn for generating and outputting the gate voltages using the aforementioned signals. The gate driver 500 may also include a plurality of signal lines SL for transferring the signals to the stages ST1-STn. The signal line SL may be disposed at a more external portion from the display area DA than the stages ST1-STn. Although indicated by one line, the signal line SL may include signal lines of which the number corresponds to the number of signals applied to the gate driver 500, or more or less. The gate driver 500 may be integrated in the peripheral area PA of the display panel 300. Alternatively, for example, the gate driver 500 may be mounted on a printed circuit board or a flexible printed circuit board electrically connected to the display panel 300.

A vertical start signal, a clock signal, and a low voltage, which are scheduled to be applied to the gate driver 500, may be applied to the gate driver 500 through the FPCB 450, which is relatively close to the gate driver 500. These signals may be transferred to the FPCB 450 through the PCB 400 from the outside, or the signal controller 600.

The gate driver 500 may be disposed in the peripheral area PA, for example, a left side, a right side, or the left side and the right side of the display area DA. The stages ST1-STn of the gate driver 500 may include a plurality of thin film transistors and at least one capacitor. At least one of the thin film transistors may be diode-connected. The thin film transistors and the capacitor may be manufactured in the same process as that of the thin film transistors and the like included in the pixel PX of the display area DA.

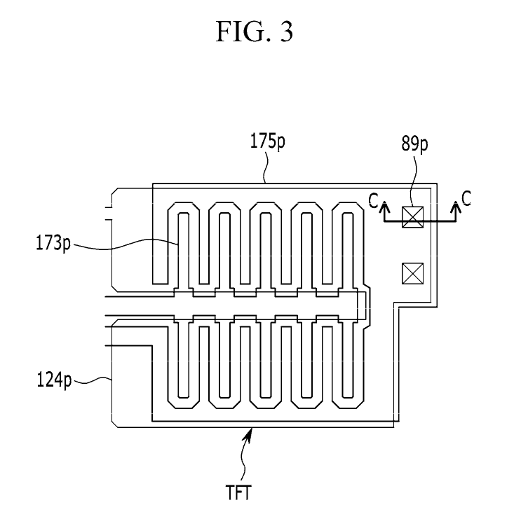

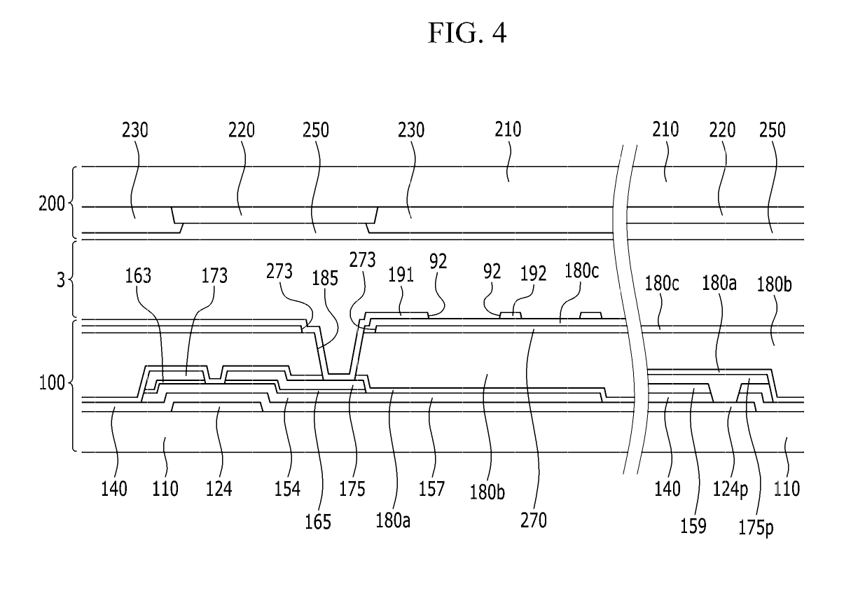

FIG. 2 is a layout view illustrating a pixel area of a display device, according to one or more exemplary embodiments. FIG. 3 is a layout view of a thin film transistor included in a gate driver of a display device, according to one or more exemplary embodiments. FIG. 4 is a cross-sectional view of the thin film transistor taken along sectional line B-B of FIG. 2 and sectional line C-C of FIG. 3, according to one or more exemplary embodiments. It is noted that FIGS. 2-4 will be described in association with a liquid crystal display device embodiment.

The display panel 300 may include a lower display panel 100, an upper display panel 200, and a liquid crystal layer 3.

The lower display panel 100 may include a gate conductor including a gate line 121 and gate electrodes 124 and 124p formed on an insulation substrate 110 made of transparent glass or plastic. It is contemplated, however, that any suitable material may be utilized in association with insulation substrate 110. The gate electrode 124 may be disposed in the display area DA, and the gate electrode 124p may be disposed in the peripheral area PA. The gate line 121 serves to transmit a gate signal, and has a wide end portion (not illustrated) connected to the gate driver 500. The wide end portion of the gate line 121 may be connected to a drain electrode (not illustrated) of each of the thin film transistors constituting the stages ST1-STn of the gate driver 500 in the peripheral area PA.

The gate line 121 mainly extends in a first (e.g., horizontal) direction. The gate line 121 may be made of a metal including, for instance, an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), titanium (Ti), and/or the like. The gate line 121 may have one conductive layer, or may have a multilayered structure including at least two conductive layers having different physical properties.

A gate insulating layer 140 is formed on the gate conductor. The gate insulating layer 140 may be made of silicon nitride (SiNx), silicon oxide (SiOx), or the like. The gate insulating layer 140 may have a multilayered structure including at least two insulating layers having different physical properties.

A semiconductor 154 including an oxide semiconductor is formed on the gate insulating layer 140. The semiconductor 154 may include at least a ternary-based semiconductor oxide containing a trivalent element (group 3A element), such as indium (In) and gallium (Ga), or a bivalent element (group 2B element), such as zinc (Zn) and oxygen (O). For example, the semiconductor 154 may include a gallium-indium-zinc oxide (IGZO). The semiconductor 154 may be formed of a single layer or multiple layers. For example, the semiconductor layer 154 may be formed of double layers; a lower layer may be an indium-gallium-zinc oxide (IGZO) layer, and an upper layer may be a gallium-zinc oxide (GZO) layer. The semiconductor 154 may include amorphous silicon or polysilicon. A portion of the semiconductor 159 may or may not be formed on the gate insulating layer 140 even at a region of the peripheral area PA at which a drain electrode 175p is formed.

A storage electrode 157 including an oxide semiconductor like the semiconductor 154 is also formed on the gate insulating layer 140. The storage electrode 157 may be integrally formed with the semiconductor 154, and, as such, may be physically connected to the semiconductor 154. The storage electrode 157 may include hydrogen diffused in the oxide semiconductor and may serve as a conductor due to a high carrier concentration. Exemplary embodiments, however, are not limited thereto. For instance, the storage electrode 157 may include fluorine diffused in the oxide semiconductor and may serve as a conductor. The storage electrode 157 may be mainly formed at a region defined by an adjacent data line 171 and an adjacent gate line 121. For example, the storage electrode 157 may be mainly formed in an opening of a corresponding pixel, e.g., a region configured for image presentation.

Although FIG. 2 illustrates the storage electrode 157 as being formed at an entire part of the opening of a pixel PX, exemplary embodiments are not limited thereto. For instance, the storage electrode 157 may be formed at some portions of the opening of the pixel PX. The storage electrode 157 is also illustrated having a single plate shape as an example, but may have any suitable pattern. For example, the storage electrode 157 may have a cutout formed at a portion that overlaps the cutout 92 of the pixel electrode 191.

Barriers 163 and 165 may be formed on the semiconductor 154. The barriers 163 and 165 may be formed of a transparent conductive oxide, such as aluminum zinc oxide (AZO), gallium zinc oxide (GZO), indium zinc oxide (IZO), indium tin oxide (ITO), etc., or a metal based on titanium (Ti), chromium (Cr), tantalum (Ta), or molybdenum (Mo). The barriers 163 and 165 serve as a diffusion barrier layer for preventing diffusion of a material, such as copper, of the source and drain electrodes 173 and 175 into the semiconductor 154. When the semiconductor 154 is made of amorphous silicon, an ohmic contact may be formed on the semiconductor 154. The ohmic contact may be formed of silicide or a material, such as n+ hydrogenated amorphous silicon doped with an n-type impurity, such as phosphorus, in a relatively high concentration.

A data conductor, including the data line 171, source electrodes 173 and 173p, and drain electrodes 175 and 175p, is formed on the barriers 163 and 165 and the gate insulating layer 140. The source electrode 173 and the drain electrode 175 are disposed in the display area DA, and the source electrode 173p and the drain electrode 175p are disposed in the peripheral area PA.

The data line 171 has a wide end portion (not illustrated) for connection with another layer or the data driver 460. For example, at a fan-out portion (not shown), the wide end portion of the data line 171 may be directly connected to the gate conductor through a contact hole (not illustrated) formed in the gate insulating layer 140. The data line 171 transfers a data signal, and mainly extends in a second (e.g., vertical) direction. The data line 171 may have curved portions to obtain maximum (or at least increased) transmittance of the display device, and the curved portions may meet each other at (or around) a middle portion of the pixel area. In this manner, the data line 171 may have a rotated V-shape.

The source electrode 173 may pertain to the data line 171, and may be disposed on the same line as the data line 171. The drain electrode 175 may extend in parallel with the source electrode 173. In this manner, the width of a thin film transistor TFT can be increased without widening an area occupied by the data conductor, thereby increasing an aperture ratio of the display device. The gate electrode 124, the source electrode 173, and the drain electrode 175 constitute a thin film transistor TFT together with the semiconductor 154, and a channel of the thin film transistor TFT is positioned in the semiconductor 154 between the source electrode 173 and the drain electrode 175. The source electrode 173 and the drain electrode 175 of the thin film transistor TFT may be oppositely configured. As described herein, an electrode connected to the data line 171 is referred to as the source electrode 173, and an electrode connected to the pixel electrode is referred to as the drain electrode 175.

The source electrode 173p and the drain electrode 175p are disposed on a semiconductor 159 and the gate electrode 124p disposed in the peripheral area PA. The gate electrode 124p, the source electrode 173p, and the drain electrode 175p constitute a thin film transistor TFT together with the semiconductor 159. As seen in FIGS. 3 and 4, the thin film transistor TFT is diode-connected. For example, the drain electrode 175p is connected to the gate electrode 124p. The drain electrode 175p may be directly connected to the gate electrode 124p through a contact hole 89p formed in the gate insulating layer 140. For example, the diode-connected thin film transistor TFT may be one of a plurality of thin film transistors TFT constituting the stages ST1 to STn of the gate driver 500. The diode-connected thin film transistor TFT may have a structure in which the source electrode 173p is directly connected to the gate electrode 124p.

When the thin film transistor TFT is the thin film transistor TFT connected to the wide end portion of the gate line 121, the drain electrode 175p may be directly connected to the wide end portion of gate line 121 through a contact hole formed in the gate insulating layer 140 instead of the gate electrode 124p. End portions of the drain electrode 175p and the gate line 121, however, may be connected to each other through a separate bridge formed at the same layer as the pixel electrode 191.

Direct connection of the data conductor to the gate conductor in the peripheral area PA may be applied to the fan-out portion as well as the gate driver 500 for wire connection. When the data conductor is directly connected to the gate conductor, a connection region can be reduced (for example, by about 50% or more). In this manner, the width of the peripheral area PA can be reduced, thereby decreasing a bezel width of the display device. However, for the direct connection, a contact hole through which a portion of the gate conductor is exposed in the gate insulating layer 140 that has been formed like the contact hole 89p is used, and an additional mask may be needed to form such a contact hole. Since the gate conductor and the data conductor are typically made of a metal, a way of physically and electrically connecting the data conductor to gate conductor may utilize a contact hole formed in a layer disposed between the gate conductor and the data conductor, and may be referred to as metal direct connection (MDC).

The data conductor may be made of a refractory metal, such as aluminum (Al), molybdenum (Mo), chromium (Cr), tantalum (Ta), and titanium (Ti), or an alloy thereof, and may have a multilayered structure including a refractory metal layer (not illustrated) and a low resistive conductive layer (not illustrated). Examples of this multilayer structure may include a double layer including a lower layer of chromium (Cr) or molybdenum (Mo) and an aluminum (Al) upper layer, and a triple layer including a molybdenum (Mo) lower layer, an aluminum (Al) intermediate layer, and a molybdenum (Mo) upper layer. It is noted, however, that the data conductor may be made of various metals or suitable conductors.

A first passivation layer 180a is formed in exposed portions of the data conductor, the gate insulating layer 140, and the semiconductor 154. The first passivation layer 180a may be made of an inorganic insulating material. For example, the first passivation layer 180a may have a dual-layer structure including a lower layer of silicon oxide and an upper layer of silicon nitride. It is also contemplated that the first passivation layer 180a may be made of an organic insulating material.

A second passivation layer 180b is disposed on the first passivation layer 180a. The second passivation layer 180b may be omitted. The second passivation layer 180b may be a color filter. The second passivation layer 180b may uniquely exhibit one of primary colors if the second passivation layer 180b is a color filter. The primary colors may be, for example, three primary colors, such as red, green, and blue, or yellow, cyan, magenta, etc. Although not illustrated, an additional color filter for exhibiting mixed colors of the primary colors or white as well as the primary colors may be further included.

A common electrode 270 may be formed on the second passivation layer 180b. The common electrode 270 may have a planar plate shape on an entire (or substantially entire) surface of the substrate 110. In other words, the common electrode 270 may have a plate-like planar shape, and may receive a common voltage supplied from the outside of the display area DA. An opening 273, however, may be formed in the common electrode 270 for connecting the pixel electrode 191 to the drain electrode 175. The opening 273 may be disposed in a region of the common electrode 270 corresponding to a periphery of the drain electrode 175. A third passivation layer 180c is disposed on the common electrode 270. The third passivation layer 180c may be made of an organic insulating material or an inorganic insulating material.

A pixel electrode 191 is formed on the third passivation layer 180c. A cutout 92 is formed on the pixel electrode 191. The pixel electrode 191 includes a plurality of branch electrodes 192 that are defined by edges of the cutout 92 and the pixel electrode 191. The branch electrode 192 of the pixel electrode 191 may have a curved edge that is substantially parallel with the curved portion of the data line 171. Opposite end portions of the branch electrode 192 of the pixel electrode 191 may be bent at an angle that is different from that of the central portion. A contact hole 185 for exposing the drain electrode 175 is formed in the first passivation layer 180a, the second passivation layer 180b, and the third passivation layer 180c. The pixel electrode 191 is physically and electrically connected to the drain electrode 175 through the contact hole 185 to receive a data voltage from the drain electrode 175.

For a relationship between the storage electrode 157, the common electrode 270, and the pixel electrode 191, on the lower substrate 110, the common electrode 270 and the pixel electrode 191 are formed to overlap and be separated from each other on the same plane, with the third passivation layer 180c disposed therebetween. In this manner, the common electrode 270 and the pixel electrode 191 constitute a first capacitor together with the insulating layer (e.g., the third passivation layer 180c) disposed therebetween. Further, on the lower substrate 110, the storage electrode 157 and the common electrode 270 are formed to overlap and be separated from each other on the same plane, with the first passivation layer 180a and the second passivation layer 180b serving as an insulating layer disposed therebetween.

The storage electrode 157 is physically connected to the semiconductor 154 of the thin film transistor TFT, and, as such, is electrically connected to the drain electrode 175 of the thin film transistor TFT. In this manner, the data voltage applied to the pixel electrode 191 through the drain electrode 175 may also be applied to the storage electrode 157. The storage electrode 157 and the common electrode 270 constitute a second storage capacitor together with the insulating layer disposed therebetween. As such, the storage electrode 157 is formed by using the semiconductor layer, thereby constituting the second storage capacitor. Accordingly, it is possible to increase the storage capacitance. The storage electrode 157 may be made of a transparent material, and, in this manner, may be formed in an opening of a pixel. Further, although the storage electrode 157 is formed in the opening to have a wide area, transmittance is not deteriorated due to the use of a transparent material.

An alignment layer (not illustrated) may be formed on the pixel electrode 191 and the third passivation layer 180c. The alignment layer may be a horizontal alignment layer, and may be rubbed in a determined direction. The alignment layer may include a photo-reactive material and may be photo-aligned.

The upper display panel 200 may include a light blocking member 220 disposed below an insulation substrate 210 made of, for instance, transparent glass or plastic. The light blocking member 220 may also be referred to as a black matrix, and may prevent light leakage or light reflection. During manufacture of the display device, the light blocking member 220 is formed on the substrate 210, however, when the display panel is formed by combining the upper display panel 200 and the lower display panel 100, the light blocking member 220 is positioned below the substrate 210 as seen in FIG. 4. Hereinafter, similar features of the upper display panel 200 will be described in a similar fashion, e.g., described as being disposed on or below insulation substrate 210.

A plurality of color filters 230 may also be disposed below the substrate 210. When the second passivation layer 180b of the lower display panel 100 serves as a color filter, the color filters 230 of the upper display panel 200 may be omitted. Further, the light blocking member 220 of the upper display panel 200 may be formed on the lower display panel 100.

An overcoat 250 is disposed below the color filters 230 and the light blocking member 220. The overcoat 250 may be made of an organic insulating material, and may prevent the color filters 230 from being exposed and provide a flat surface. The overcoat 250 may be omitted. An alignment layer (not shown) may be formed below the overcoat 250.

The liquid crystal layer 3 may include a plurality of liquid crystal molecules having positive dielectric anisotropy or negative dielectric anisotropy. The liquid crystal molecules included in the liquid crystal layer 3 may be arranged so that a long axis direction is aligned parallel to the lower display panel 100 and the upper display panel 200 in a state where no electric field is generated.

According to one or more exemplary embodiments, the pixel electrode 191 receives a data voltage from the data line 171 through the thin film transistor TFT, and the common electrode 270 receives a constant magnitude, common voltage from a common voltage source disposed outside of the display area DA. In this manner, the pixel electrode 191 and the common electrode 270 generate an electric field, and liquid crystal molecules of the liquid crystal layer 3 disposed between the pixel electrode 191 and the common electrode 270 are rotated in a direction parallel to the direction of the electric field. Polarization of light passing through the liquid crystal layer varies according to the rotational direction of the liquid crystal molecules as controlled via the generated electric field.

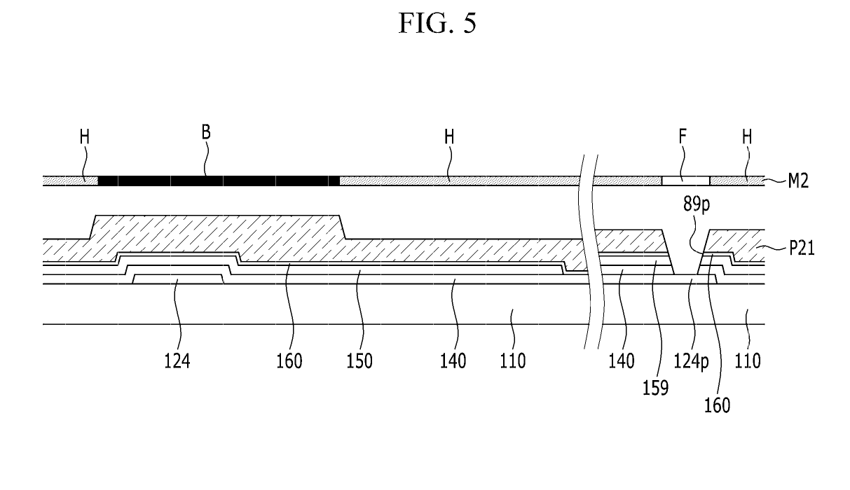

Hereinafter, a method of manufacturing a display device will be described with reference to FIGS. 5 to 11, as well as FIGS. 1-4. Since the upper display panel 200 has a relatively simple layer structure, the method will focus on the lower display panel 100.

FIGS. 5 to 11 are respective cross-sectional views of a display device at various stages of manufacture, according to one or more exemplary embodiments.

Referring to FIG. 5, a conductive material, such as a metal, is stacked on the insulation substrate 110, and is patterned using a photosensitive material, such as photoresist and a first mask (not illustrated) to form a gate conductor including the gate line 121 and the gate electrodes 124 and 124p. Next, the gate insulating layer 140 is formed by stacking an insulating material, such as silicon nitride or silicon oxide, and the semiconductor layer 150 and 159 is formed by stacking a semiconductor material, such as an oxide semiconductor on the gate insulating layer 140. Next, the barrier layer 160 is formed by stacking a conductor, such as AZO, GZO, IZO, ITO, etc., on the semiconductor layer 150 and 159.

A photosensitive material is stacked on the semiconductor layer 150 and 159, and a first photosensitive film pattern P21 having different height portions is formed using a second mask M2. The second mask M2 includes a complete-transmissive area F through which light is transmitted, a transflective area H through which light is partially transmitted, and a blocking area B for blocking light. For a photosensitive material having positive photosensitivity in which a portion irradiated with light remains, a thick portion of the first photosensitive film pattern P21 may correspond to the blocking area B of the second mask M2, and a thin portion thereof may be a portion that is exposed to the transflective area H of the second mask M2. A portion at which the photosensitive material is completely removed, and, as such, no first photosensitive film pattern P21 is formed may be a portion that is exposed to the complete-transmissive area F of the second mask M2. For a photosensitive material having negative photosensitivity, transparency of the second mask M2 corresponding to the first photosensitive film pattern P21 is reversed.

After the first photosensitive film pattern P21 is formed using the second mask M2, the barrier layer 160, the semiconductor layer 150, and the gate insulating layer 140 are etched using the first photosensitive film pattern P21 as an etching mask to form the contact hole 89p for exposing the gate electrode 124p. Another contact hole (not illustrated) for exposing the gate conductor for direct connection with the data conductor in the peripheral area PA is formed.

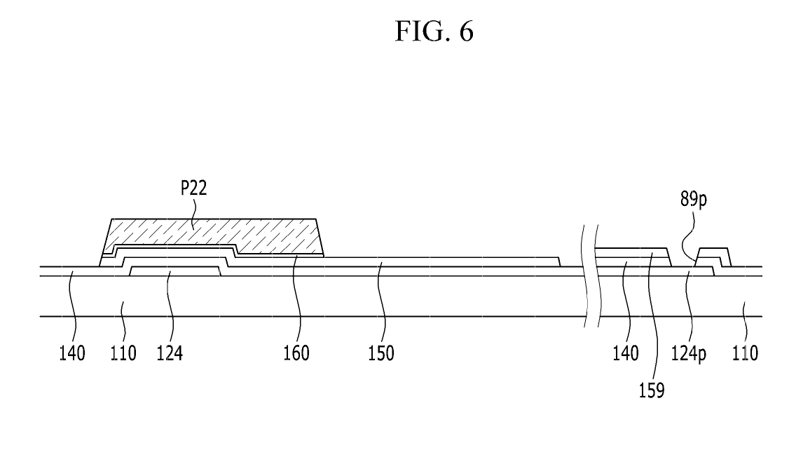

Next, referring to FIG. 6, a thin portion of the first photosensitive film pattern P21 is removed by partially etching the first photosensitive film pattern P21. In this manner, a thick portion of the first photosensitive film pattern P21 is also etched, such that a width and a height thereof is reduced to become the second photosensitive film pattern P22. The first-stacked photosensitive material may remain as the second photosensitive film pattern 22 at a region corresponding to the thin film transistor TFT, and may be completely removed at a region corresponding to the storage electrode 157. The second photosensitive film pattern 22 is used as an etching mask to remove the barrier layer 160. A portion of the barrier layer 160 that corresponds to the thin film transistor TFT may remain.

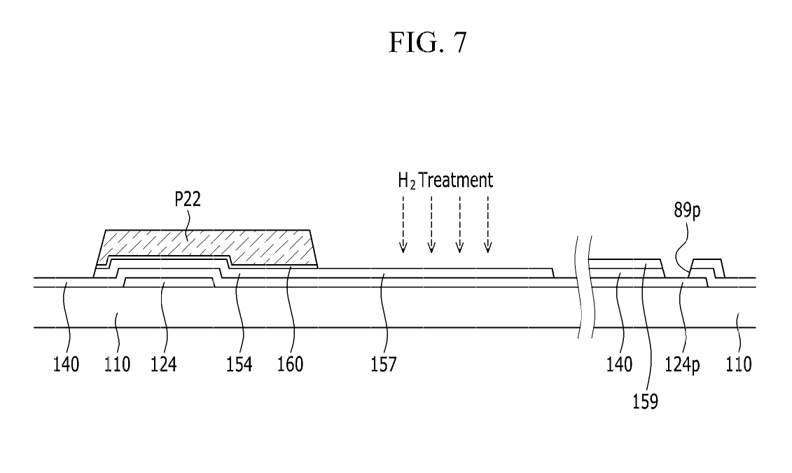

With reference to FIG. 7, a plasma treatment is performed in a hydrogen gas atmosphere. In this manner, hydrogen is diffused in a portion of the semiconductor layer 150, which is not covered by the second photosensitive film pattern and is exposed. In this manner, semiconductor layer 150 may serve as a conductor. A portion of the semiconductor layer 150 serving as a conductor becomes a storage electrode 157. The storage electrode 157 is connected to a portion of the semiconductor layer 150, which does not serve as a conductor. Heat treatment and plasma treatment may be performed to accomplish hydrogen diffusion and stability. It is also contemplated that the plasma treatment may be performed in an atmosphere of a fluorine-based gas, such as CF₄ or CF₆, and, as such, fluorine may be diffused in an exposed portion of the semiconductor layer 150, allowing the semiconductor to serve as a conductor. The portion of the semiconductor layer disposed under the second photosensitive film pattern P22 forms the semiconductor layer 154.

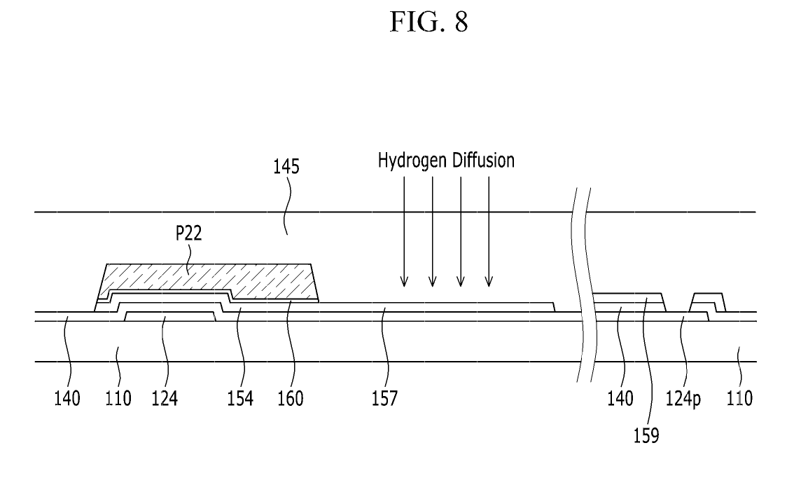

As seen in FIG. 8, a silicon nitride layer 145 is stacked on the second photosensitive film pattern 22 and the storage electrode 157, and then heat treatment is performed. Thereafter, hydrogen included in the silicon nitride is diffused into the storage electrode 157, thereby further increasing the conductivity of the storage electrode 157. As a thickness of the silicon nitride layer 145 is increased, a greater amount of hydrogen is diffused into the semiconductor of the storage electrode 157. Accordingly, as the thickness of the silicon nitride layer 145 is increased, an increase in the conductivity of the storage electrode 157 is a direct benefit. Next, the silicon nitride layer 145 and the second photosensitive film pattern 22 are removed.

As previously described, the storage electrode 157 may be formed using a second mask M2, which is used to form a contact hole 89p for a metal direct connection in the gate insulating layer 140. Accordingly, no additional mask or complex process is required to form the storage electrode 157. One of the hydrogen plasma treatment of FIG. 7 and stacking of the silicon nitride layer 145 of FIG. 8 may be omitted.

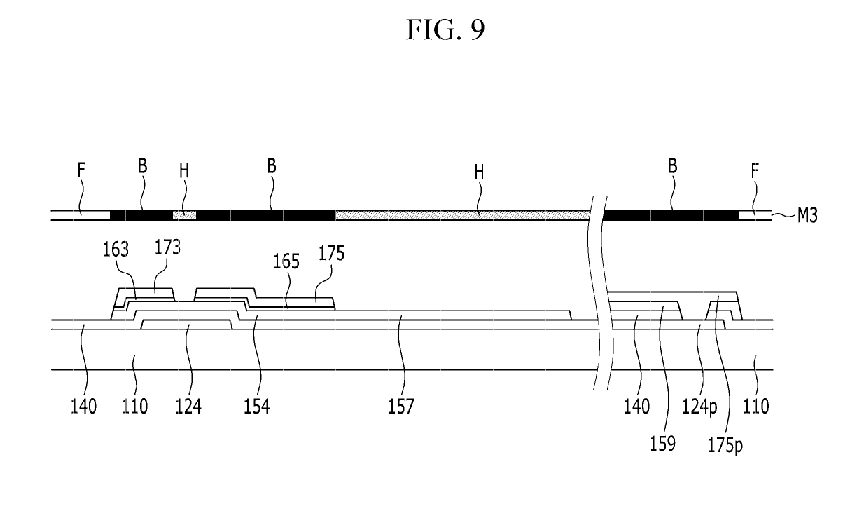

Referring to FIG. 9, a conductive material, such as a metal, is stacked, and is patterned using a photosensitive material and a third mask M3 to form a data conductor including the data line 171, the source electrode 173, and the drain electrodes 175 and 175p. In this manner, the drain electrode 175p may be directly connected to the gate electrode 124p through the contact hole 89p, which is formed using the second mask M2. This metal direct connection may be made at a portion, such as a fan-out portion of the peripheral area PA.

Similar to the second mask M2, the third mask M3 includes a complete-transmissive area F, a transflective area H, and a blocking area B. Accordingly, a plurality of layers may be selectively etched by forming a photosensitive film pattern having different thicknesses by use of the third mask M3. For example, when a photosensitive material having positive photosensitivity is used, a data conductor may be formed at a portion corresponding to the blocking area B of the third mask M3. The barrier layer 160 is removed at a portion corresponding to the transflective area H of the third mask M3, and the barriers 163 and 165 may be formed between the source electrode 173 and the semiconductor 154 and between the drain electrode 175 and the semiconductor 154, respectively. Even a portion of the semiconductor layer 154 may be removed at a portion corresponding to the complete-transmissive area F of the third mask M3, to form the semiconductor 154 of the thin film transistor TFT.

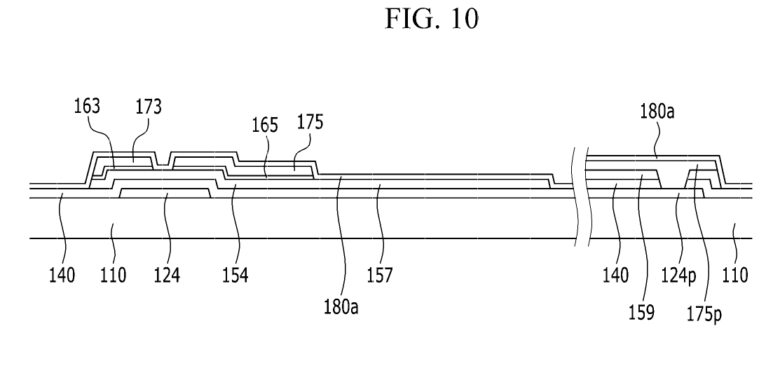

As seen in FIG. 10, the first passivation layer 180a is formed by stacking an inorganic insulating material or the like. The first passivation layer 180a may have a dual-layer structure including a silicon oxide layer and a silicon nitride layer, or may have a multiple-layer structure including more layers. A heat treatment may be performed after the first passivation layer 180a is formed. In this manner, hydrogen may be diffused into the storage electrode 157, thereby increasing conductivity of the storage electrode 157.

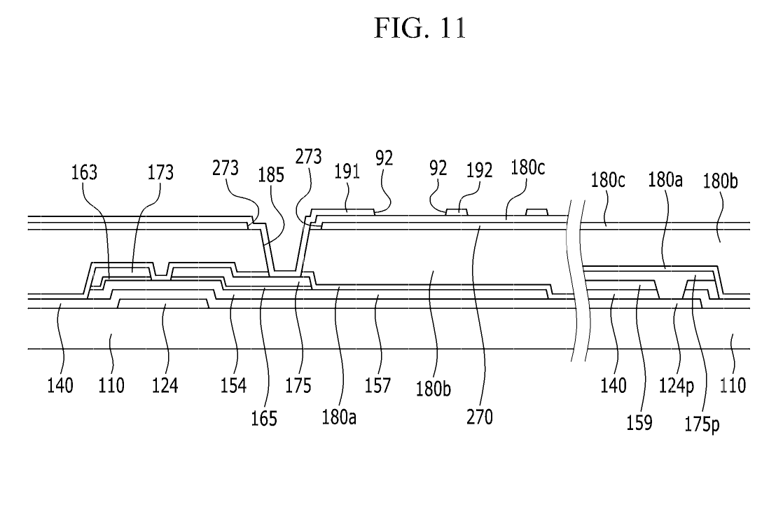

Referring to FIG. 11, an organic insulating material is stacked, and is patterned using a fourth mask (not illustrated) to form a second passivation layer 180b. Next, a transparent conductive material, such as AZO, GZO, ITO, IZO, etc., is stacked and patterned using a fifth mask (not illustrated) to form the common electrode 270 having the opening 273. Next, an organic insulating material or an inorganic insulating material is stacked, and is patterned using a sixth mask (not illustrated) to form the third passivation layer 180c in which a contact hole for exposing the drain electrode 175 is formed. A transparent conductive oxide, such as AZO, GZO, ITO, IZO, etc., is stacked and patterned using a seventh mask (not illustrated) to form the pixel electrode 191, which is physically and electrically connected to the drain electrode 175 of the thin film transistor TFT. Next, an alignment layer (not illustrated) may be formed on the pixel electrode 191.

FIG. 12 is a layout view illustrating a pixel area of a display device, according to one or more exemplary embodiments. FIG. 13 is a cross-sectional view of a pixel taken along sectional line D-D of FIG. 12, according to one or more exemplary embodiments. FIGS. 12 and 13 will be described in association with an organic light emitting display device embodiment. It is noted that the display device of FIGS. 12 and 13 is relatively similar to the display device of FIGS. 2-4, and, therefore, to avoid obscuring exemplary embodiments described herein, duplicative descriptions may be omitted or described will limited detail.

The display device includes a transparent insulation substrate 110 made of, e.g., glass or plastic, and a plurality of layers formed thereon. A blocking layer 111 may be formed directly on the lower substrate 110 to prevent diffusion of impurities, which may cause degradation of semiconductor characteristics and moisture penetration.

A first semiconductor 154a and a second semiconductor 154b may be formed on the blocking layer 111. The first semiconductor 154a may have a channel area (not illustrated), and a source area (not illustrated) and a drain area (not illustrated), which are disposed at opposite sides of the channel area. The source area and the drain area are formed by being doped. Similarly, the second semiconductor 154b may have a channel area 152b, and a source area 153b and a drain area 155b at opposite sides of the channel area 152b. The source area 153b and the drain area 155b are formed by being doped. For example, for the doping, ionized boron (B) may be used for forming a p region, and ionized phosphorus (P) gas may be used for forming an n region. The first semiconductor 154a and the second semiconductor 154b may contain polysilicon.

Similar to the second semiconductor 154b, the storage electrode 157 containing polysilicon may also be formed on the blocking layer 111. The storage electrode 157 may be doped like the source area 153b to serve as a conductor. The storage electrode 157 may be formed in a region defined by an adjacent data line 171 and a driving voltage line 172. For example, the storage electrode 157 may be formed in an opening of a pixel PX. The storage electrode 157 may be integrally formed with the second semiconductor 154b, and may be physically connected to the source area 153b of the second semiconductor 154b. The storage electrode 157 may be integrally formed with the first semiconductor 154a, and may be physically connected to the drain area of the first semiconductor 154a. The storage electrode 157 may be formed separately from the first semiconductor 154a and the second semiconductor 154b to receive a different kind of voltage from that of the data voltage. It is noted that the first semiconductor 154a and the second semiconductor 154b may include an oxide semiconductor or amorphous silicon, and the storage electrode 157 may include an oxide semiconductor.

The gate insulating layer 140 (made of a silicon oxide, a silicon nitride, or the like) is formed on the first semiconductor 154a, the second semiconductor 154b, and the storage electrode 157. The gate insulating layer 140 may be formed as a single layer or as multiple layers. A gate conductor including the gate line 121, the first gate electrode 124a, and a second gate electrode 124b is formed on the gate insulating layer 140. The gate line 121, serving to transfer a gate signal, may mainly extend in a first (e.g., horizontal) direction, and the first gate electrode 124a may upwardly extend from the gate line 121. The second gate electrode 124b is separated from the gate line 121. The second gate electrode 124b may include another storage electrode (not illustrated) that longitudinally extends in the vertical direction. The first gate electrode 124a may be disposed overlapping the channel area of the first semiconductor 154a, and the second gate electrode 124b may be disposed overlapping the channel area 152b of the second semiconductor 154b.

A first passivation layer 180a is disposed on the gate insulating layer 140 and the gate conductor. The first passivation layer 180a and the gate insulating layer 140 may include a contact hole for exposing the source area of the first semiconductor 154a, a contact hole 185a for exposing the drain area of the first semiconductor 154a, a contact hole 183b for exposing the source area of the second semiconductor 154b, and a contact hole 185b for exposing the drain area 155b of the second semiconductor 154b. The first passivation layer 180a also includes a contact hole 184 for exposing the second gate electrode 124b.

A data conductor including the data line 171, the driving voltage line 172, a first source electrode 173a, a second source electrode 173b, a first drain electrode 175a, and a second drain electrode 175b may be formed on the first passivation layer 180a.

The data line 171 serving to transfer a data voltage and the driving voltage line 172 serving to transfer a driving voltage may mainly extend in a second (e.g., vertical) direction, and may cross the gate line 121. The first source electrode 173a extends from the data line 171 toward the first gate electrode 124a. The second source electrode 173b extends from the driving voltage line 172 toward the second gate electrode 124b. When the second gate electrode 124b includes a storage electrode, the driving voltage line 172 may have a portion overlapping the storage electrode.

The first drain electrode 175a and the second drain electrode 175b are disposed separately from each other, and are also separated from the data line 171 and the driving voltage line 172. The first source electrode 173a and the first drain electrode 175a are disposed on the first semiconductor 154a to face each other, and the second source electrode 173b and the second drain electrode 175b are disposed on the second semiconductor 154b to face each other. The first source electrode 173a and the first drain electrode 175a may be respectively connected to the source area and the drain area of the first semiconductor 154a through the contact holes 183a and 185a. The first drain electrode 175a may be connected to the second gate electrode 124b through the contact hole 184. The second source electrode 173b and the second drain electrode 175b may be respectively connected to the source area 153b and the drain area 155b of the second semiconductor 154b through the contact holes 183b and 185b.

The first gate electrode 124a, the first source electrode 173a, and the first drain electrode 175a constitute a switching thin film transistor Qs together with the first semiconductor 154a, and the second gate electrode 124b, the second source electrode 173b, and the second drain electrode 175b constitute a driving thin film transistor Qd together with the second semiconductor 154b. Thin film transistors Qs and Qd may be referred to as top-gate thin film transistors since the gate electrodes 124a and 124b are positioned above the semiconductors 154a and 154b. This top-gate thin film transistor may also be applied to the liquid crystal display panel of FIGS. 2-4. The structures of the switching thin film transistor Qs and the driving thin film transistor Qd are not limited thereto, and may be variously changed. For example, the thin film transistors Qs and Qd may be bottom-gate thin film transistors, in which the gate electrode is disposed below the semiconductor as in the thin film transistor described in association with FIGS. 2-4.

The second passivation layer 180b may be made of an inorganic insulating material, such as silicon oxide or silicon nitride, and may be disposed on the data conductor. The second passivation layer 180b may have a flat surface to increase light-emitting efficiency of an organic light emitting element, which is formed thereon. A contact hole 185c for exposing the second drain electrode 175b may be formed in the second passivation layer 180b. The pixel electrode 191 may be formed on the second passivation layer 180b. The pixel electrode 191 of each pixel is physically and electrically connected to the second drain electrode 175b through the contact hole 185c of the second passivation layer 180b. The pixel electrode 191 may be made of a reflective conductive material or a transflective conductive material, and may be made of a transparent conductive material. The pixel electrode 191 may be formed as a single layer or as multiple layers.

A pixel definition layer (or referred to as a partition wall) 360 having a plurality of openings for exposing the pixel electrodes 191 may be disposed on the second passivation layer 180b. The openings of the pixel definition layer 360 for exposing the pixel electrode 191 may respectively define pixel areas. The pixel definition layer 360 may be omitted.

An emission member 370 is disposed on the pixel definition layer 360 and the pixel electrode 191. The emission member 370 may include a first organic common layer 371, a plurality of emission layers 373, and a second organic common layer 375, which are sequentially stacked on one another. The first organic common layer 371 may include at least one of a hole injecting layer (HIL) and a hole transport layer (HTL). When including both of the hole injecting layer and the hole transport layer, the hole injecting layer and the hole transport layer may be sequentially stacked on one another. The first organic common layer 371 may be formed over an entire display area in which pixels are disposed, or may be formed in each pixel area.

The emission layers 373 may be respectively disposed on the pixel electrode 191 of the corresponding pixels. The emission layers 373 may be made of an organic material for intrinsically displaying light of primary colors, such as red, green, and blue, and may have a structure in which a plurality of organic material layers for displaying light of different colors are stacked. For example, a red organic emission layer is stacked on a first organic common layer 371 of a pixel for displaying red, a green organic emission layer is stacked on a first organic common layer 371 of a pixel for displaying green, and a blue organic emission layer is stacked on a first organic common layer 371 of a pixel for displaying blue. However, exemplary embodiments are not limited thereto. For instance, an organic emission layer for displaying one primary color may be stacked on a pixel for displaying a different color. As another example, the emission layers 373 may include a white emission layer for displaying white. Some of the emission layers 373 may be disposed overlapping the driving thin film transistor Qd.

A second organic common layer 375 may include at least one of an electron transport layer (ETL) and an electron injecting layer (EIL). When including both of the electron transport layer and the electron injecting layer, the electron transport layer and the electron injecting layer may be sequentially stacked on one another. A common electrode 270 serving to transfer a common voltage may be formed on the emission member 370. The common electrode 270 may be made of a transparent conductive material, such as AZO, GZO, ITO, IZO, etc., or may be formed by thinly stacking a metal, such as calcium (Ca), barium (Ba), magnesium (Mg), aluminum (Al), or silver (Ag), to have light permeability.

The pixel electrode 191, the emission member 370, and the common electrode 270 of each pixel constitute a light-emitting device. Further, the storage electrode 157 and the common electrode 270, which are disposed overlapping each other, may constitute a storage capacitor. As such, the storage electrode 157 may be formed using a semiconductor layer, thereby constituting a storage capacitor. In this manner, it is possible to increase a storage capacitance. The storage electrode 157 is made of a transparent material, and, as such, may be formed in an opening of one pixel. Further, although the storage electrode 157 is formed in the opening to have a wide area, transmittance is not deteriorated.

An encapsulating substrate 210 is disposed above the common electrode 270. The encapsulation substrate 210 serves to encapsulate the emission member 370 and the common electrode 270 to prevent moisture or oxygen from affecting the performance of the organic light emitting diode.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A display device, comprising:
a substrate;
a thin film transistor disposed on the substrate, the thin film transistor comprising a drain electrode and a semiconductor layer;
a storage electrode disposed at a same layer as the semiconductor layer, the storage electrode electrically connected to the drain electrode;
a pixel electrode disposed on the substrate, the pixel electrode being electrically connected to the drain electrode; and
a common electrode disposed on the substrate.

2. The display device of claim 1, further comprising
an insulating layer disposed between the storage electrode and the common electrode,
wherein the storage electrode, the common electrode, and the insulating layer constitute a storage capacitor.

3. The display device of claim 2, wherein the storage electrode overlaps the pixel electrode.

4. The display device of claim 2, wherein the storage electrode is physically connected to the drain electrode.

5. The display device of claim 2, wherein the storage electrode comprises an oxide semiconductor.

6. The display device of claim 5, wherein the oxide semiconductor comprises diffused hydrogen or diffused fluorine.

7. The display device of claim 2, wherein the storage electrode comprises doped polysilicon.

8. The display device of claim 2, wherein the common electrode is disposed between the storage electrode and the pixel electrode.

9. The display device of claim 2, wherein the insulating layer comprises:
a first passivation layer disposed on the storage electrode; and
a second passivation layer disposed on the first passivation layer.

10. The display device of claim 9, wherein the first passivation layer comprises silicon nitride.

11. A method of manufacturing a display device, the method comprising:
forming a gate electrode on a substrate;
forming a gate insulating layer on the substrate;
forming a semiconductor layer on the gate insulating layer;
forming a photosensitive film pattern covering a first region of the semiconductor layer corresponding to a thin film transistor and exposing a second region of the semiconductor layer corresponding to a storage electrode;
forming the storage electrode by diffusing hydrogen or fluorine in the second region, the storage electrode being conductive;
removing the photosensitive film pattern;
forming, on the substrate, a source electrode and a drain electrode; and
forming, on the substrate, a common electrode.

12. The method of claim 11, wherein the diffusing of the hydrogen or the fluorine comprises performing a plasma treatment in a hydrogen gas atmosphere or a fluorine-based gas atmosphere.

13. The method of claim 11, wherein the diffusing of the hydrogen comprises:
forming a silicon nitride film; and
performing a heat treatment.

14. The method of claim 11, further comprising
forming an insulating layer between the storage electrode and the common electrode,
wherein the storage electrode, the common electrode, and the insulating layer constitute a storage capacitor.

15. The method of claim 14, wherein the forming of the insulating layer comprises:
forming a first passivation layer on the storage electrode;
performing a heat treatment; and
forming a second passivation layer on the first passivation layer.

16. The method of claim 11, wherein:
the gate electrode is a first gate electrode formed in a display area; and
the method further comprises:
forming a second gate electrode in a peripheral area in association with the formation of the first gate electrode; and
forming, before forming the photosensitive film pattern, a contact hole exposing a portion of the second gate electrode.

17. The method of claim 16, wherein the photosensitive film pattern is formed by etching a photosensitive film pattern associated with forming the contact hole.

18. The method of claim 11, further comprising:
forming a pixel electrode,
wherein the storage electrode and the pixel electrode overlap each other.

19. The method of claim 11, wherein the storage electrode is physically connected to the drain electrode.

20. The method of claim 11, wherein the storage electrode comprises a doped oxide semiconductor.
